(19) United States
(12) Patent Application Publication
(10) Pub. No.: US 2018/0122749 A1
(43) Pub. Date: May 3, 2018

(54) SEMICONDUCTOR WAFER, SEMICONDUCTOR PACKAGE AND METHOD FOR MANUFACTURING THE SAME

(71) Applicant: Advanced Semiconductor Engineering, Inc., Kaohsiung (TW)

(72) Inventors: Ying-Chih LEE, Kaohsiung (TW); Chin-Cheng KUO, Kaohsiung (TW); Yung-Hui WANG, Kaohsiung (TW); Wei-Hong LAI, Kaohsiung (TW); Chung-Ting WANG, Kaohsiung (TW); Hsiao-Yen LEE, Kaohsiung (TW)

(73) Assignee: Advanced Semiconductor Engineering, Inc.

(21) Appl. No.: 15/340,808

(22) Filed: Nov. 1, 2016

(51) Int. Cl. H01L 23/00; H01L 23/48; H01L 21/768; H01L 21/56

(52) U.S. Cl. CPC H01L 23/562; H01L 23/481; H01L 24/13; H01L 24/16; H01L 2224/13026; H01L 21/56; H01L 2224/0401; H01L 2224/05025; H01L 21/76898

(57) ABSTRACT

A semiconductor wafer includes a substrate structure, a first insulation layer, a conductive layer and a second insulation layer. The substrate structure defines a via. The first insulation layer covers a surface of the substrate structure. The first insulation layer extends into the via, covers a lateral wall of the via and exposes a bottom surface at a bottom of the via. The conductive layer covers the first insulation layer and the bottom surface exposed by the first insulation layer. The second insulation layer covers the conductive layer. A warpage of the semiconductor wafer is less than 550 micrometers.

### BACKGROUND

### 1. Technical Field

The present disclosure relates to a semiconductor wafer, a semiconductor package and method for manufacturing the same, and, more particularly, to a semiconductor wafer having a low warpage, a semiconductor package having insulation layers with either, or both, a low modulus of elasticity substantially or a low coefficient of thermal expansion (CTE) and method for manufacturing the same.

### 2. Description of the Related Art

A three-dimensional (3D) semiconductor package may be subject to warpage due to its asymmetrical structure and characteristic mismatch between adjacent layers, such as a mismatch of CTE.

To alleviate warpage, a thickness of the semiconductor package may be increased. However, an increase in thickness of the semiconductor package presents a conflict with the miniaturization trend of electronic products.

### SUMMARY

In some embodiments, a semiconductor wafer includes a substrate structure, a first insulation layer, a conductive layer and a second insulation layer. The substrate structure defines a via. The first insulation layer covers a surface of the substrate structure. The first insulation layer extends into the via, covers a lateral wall of the via and exposes a bottom surface at a bottom of the via. The conductive layer covers the first insulation layer and the bottom surface exposed by the first insulation layer. The second insulation layer covers the conductive layer. A warpage of the semiconductor wafer is less than 550 micrometers.

In some embodiments, a semiconductor package includes a substrate structure, a first insulation layer, a conductive layer and a second insulation layer. The substrate structure defines a via. The first insulation layer covers a surface of the substrate structure. The first insulation layer extends into the via, covers a lateral wall of the via and exposes a bottom surface at a bottom of the via. The conductive layer covers the first insulation layer and the bottom surface exposed by the first insulation layer. The second insulation layer covers the conductive layer. A modulus of elasticity of the first insulation layer and a modulus of elasticity of the second insulation layer are each less than 1.7 GPa.

In some embodiments, a method for manufacturing a semiconductor wafer includes: providing a substrate structure defining a via; forming a first insulation layer over a surface of the substrate structure and extending into the via to cover a lateral wall of the via and expose a bottom surface at a bottom of the via; forming a conductive layer over the first insulation layer and the bottom surface exposed by the first insulation layer; and forming a second insulation layer over the conductive layer. A warpage of the semiconductor wafer is less than 550 micrometers.

### BRIEF DESCRIPTION OF THE DRAWINGS

Aspects of some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1 is a cross-sectional view of a semiconductor wafer in accordance with some embodiments of the present disclosure;

FIG. 2 is a cross-sectional view of a semiconductor package in accordance with some embodiments of the present disclosure;

FIG. 3A, FIG. 3B, FIG. 3C, FIG. 3D, FIG. 3E, FIG. 3F and FIG. 3G illustrate a method of manufacturing a semiconductor wafer in accordance with some embodiments of the present disclosure;

FIG. 4 is a cross-sectional view of a semiconductor package in accordance with some embodiments of the present disclosure;

FIG. 5A is a top view of a semiconductor wafer in accordance with some embodiments of the present disclosure;

FIG. 5B is a top view of a semiconductor package in accordance with some embodiments of the present disclosure;

FIG. 5C is a cross-sectional view of a semiconductor package in accordance with some embodiments of the present disclosure; and

FIG. 6 is a cross-sectional view of a semiconductor package in accordance with some embodiments of the present disclosure.

### DETAILED DESCRIPTION

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “over”, “above”, “upper”, “on” and the like, may be used herein for ease of description to describe one component or feature's relationship to another component(s) or feature(s) as illustrated in the figures. The present disclosure is intended to encompass different orientations of a device in use or operation in addition to the orientation depicted in the figures. The device may be otherwise oriented (rotated 90 degrees or at other orientations) and the spatially relative descriptors used herein may likewise be interpreted accordingly.

The following description is directed to a semiconductor wafer, which, in some embodiments, includes at least two insulation layers and at least one conductive layer disposed between the insulation layers. The semiconductor wafer is configured to have a warpage less than (e.g., substantially less than) about 550 micrometers at room temperature, which meets the specification for wafer warpage. As used herein, “room temperature” refers to a temperature of about 25° C.

The following description is also directed to a semiconductor package. The semiconductor package may include various types of devices such as semiconductor devices, micro-electro-mechanical system (MEMS) devices, electronic devices, optical devices or other suitable devices. In some embodiments, the semiconductor package includes at least two insulation layers and at least one conductive layer disposed between the insulation layers. In some embodiments, a modulus of elasticity of each of the insulation layers is less than (e.g., substantially less than) about 1.7 GPa at room temperature. In some embodiments, a CTE of each of the insulation layers is less than (e.g., substantially less than) about 46 ppm/° C. within a temperature range lower than its transition temperature. The insulation layers each having the modulus of elasticity and the CTE lower than the aforementioned values are included to alleviate warpage, thereby improving reliability.

The following description is also directed to a method for manufacturing a semiconductor wafer having a warpage less than (e.g., substantially less than) about 550 micrometers.

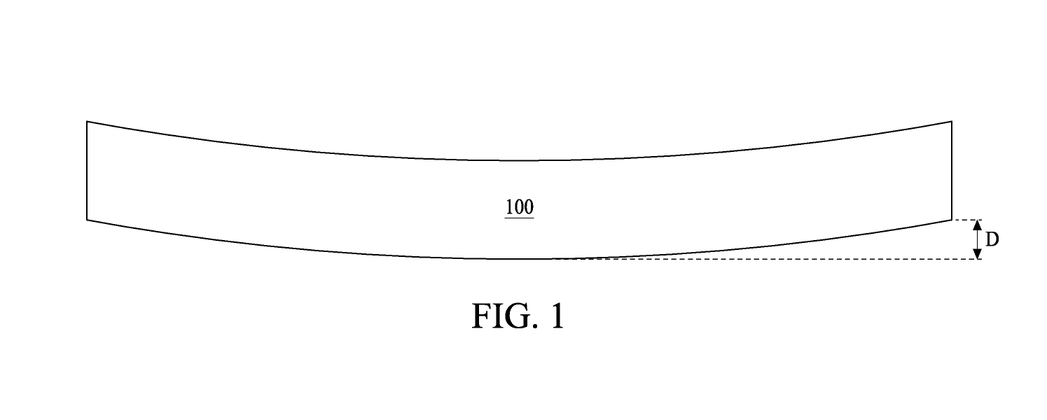

FIG. 1 is a cross-sectional view of a semiconductor wafer 100 in accordance with some embodiments of the present disclosure. As depicted in FIG. 1, a warpage D of the semiconductor wafer 100 is less than (e.g., substantially less than) about 550 micrometers at room temperature.

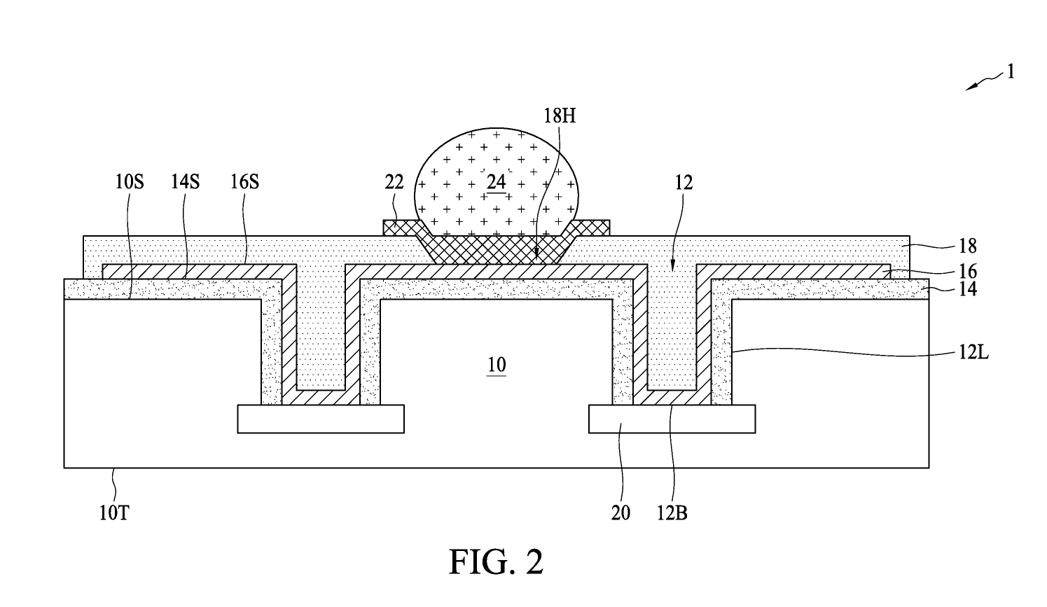

FIG. 2 is a cross-sectional view of a semiconductor package 1 in accordance with some embodiments of the present disclosure. Referring to FIG. 2, the semiconductor package 1 includes a substrate structure 10, a first insulation layer 14, a conductive layer 16 and a second insulation layer 18. In some embodiments, the substrate structure 10 may be a semiconductor substrate such as a bulk semiconductor substrate. The bulk semiconductor substrate may include an elemental semiconductor such as silicon or germanium; a compound semiconductor such as silicon germanium, silicon carbide, gallium arsenic, gallium phosphide, indium phosphide, or indium arsenide; or combinations thereof. In some embodiments, the substrate structure 10 is a multi-layered substrate such as a silicon-on-insulator (SOI) substrate, which includes a bottom semiconductor layer, a buried oxide layer (BOX) and a top semiconductor layer. The substrate structure 10 has or defines at least one via 12. In some embodiments, the via 12 does not extend through the substrate structure 10, and exposes a wiring 20 embedded in the substrate structure 10. In some embodiments, the wiring 20 is an electrical terminal of a device formed in the substrate structure 10. For example, the wiring 20 may be a contact pad, a trace, a conductive pillar or other conductive structure formed in the substrate structure 10.

The first insulation layer 14 covers a first surface 10S (e.g., a top surface) of the substrate structure 10. The first insulation layer 14 extends into the via 12, covers a lateral wall 12L of the via 12 and exposes a bottom surface 12B through an opening at a bottom of the via 12. In some embodiments, the bottom surface 12B is an exposed surface of the wiring 20, and thus the first insulation layer 14 exposes the wiring 20 through the via 12. In some embodiments, the first insulation layer 14 is made of a photosensitive material which can be patterned by photolithography techniques, and thus process steps are simplified and reduced. In some embodiments, a curing temperature of the first insulation layer 14 ranges from about 180° C. to about 220° C., such as, for example, about 200° C. In some embodiments, a transition temperature (Tg) of the first insulation layer 14 is about 230° C., but is not limited thereto. A modulus of elasticity of the first insulation layer 14 is less than (e.g., substantially less than) about 1.7 GPa at room temperature. In some embodiments, the modulus of elasticity of the first insulation layer 14 is less than or equal to about 1.4 GPa at room temperature. A CTE of the first insulation layer 14 is less than (e.g., substantially less than) about 46 ppm/° C. within a temperature range lower than its transition temperature. In some embodiments, the CTE of the first insulation layer 14 is less than or equal to about 39 ppm/° C. within a temperature range lower than its transition temperature. In some embodiments, a thickness of the first insulation layer 14 ranges from about 5 micrometers to about 20 micrometers, such as, for example about 14 micrometers, but is not limited thereto.

The conductive layer 16 covers a surface 14S (e.g., a top surface) of the first insulation layer 14 and extends into the via 12 to cover the bottom surface 12B exposed by the first insulation layer 14. In some embodiments, the conductive layer 16 is in contact with the wiring 20 exposed by the first insulation layer 14 through the via 12, thereby electrically connecting to the wiring 20. In some embodiments, the conductive layer 16 is configured as a redistribution layer (RDL). An example of a material of the conductive layer 16 is copper (Cu). In some embodiments, a thickness of the conductive layer 16 ranges from about 3 micrometers to about 15 micrometers, such as, for example about 4.5 micrometers, but is not limited thereto.

The second insulation layer 18 covers a surface 16S (e.g., a top surface) of the conductive layer 16 and extends into the via 12. In some embodiments, the second insulation layer 18 has or defines an opening 18H exposing a portion of the conductive layer 16. In some embodiments, the second insulation layer 18 is made of a photosensitive material which can be patterned by photolithography techniques, and thus process steps are simplified and reduced. The first insulation layer 14 and the second insulation layer 18 may be made of the same photosensitive material, but also may be made of different materials. In some embodiments, a thickness of the second insulation layer 18 ranges from about 5 micrometers to about 20 micrometers, such as, for example, about 14 micrometers, but is not limited thereto.

In some embodiments, a curing temperature of the second insulation layer 18 ranges from about 180° C. to about 220° C., such as, for example, about 200° C. In some embodiments, a transition temperature (Tg) of the second insulation layer 18 is about 230° C., but is not limited thereto. A modulus of elasticity of the second insulation layer 18 is less than (e.g., substantially less than) about 1.7 GPa at room temperature. In some embodiments, the modulus of elasticity of the second insulation layer 18 is less than or equal to about 1.4 GPa at room temperature. A CTE of the second insulation layer 18 is less than (e.g., substantially less than) about 46 ppm/° C. within a temperature range lower than its transition temperature. In some embodiments, the CTE of the second insulation layer 18 is less than or equal to about 39 ppm/° C. within a temperature range lower than its transition temperature.

In some embodiments, the semiconductor package 1 further includes a conductive pad 22 and a conductive bump 24. The conductive pad 22 is electrically connected to the conductive layer 16 through the opening 18H of the second insulation layer 18. The conductive bump 24 is disposed on and electrically connected to the conductive pad 22. In some embodiments, the conductive pad 22 is configured as an under bump metallurgy (UBM), and the conductive bump 24 is configured as an external terminal such as a solder ball. The conductive bump 24 can be electrically connected to another conductive structure such as a chip, thereby forming a 3D package structure.

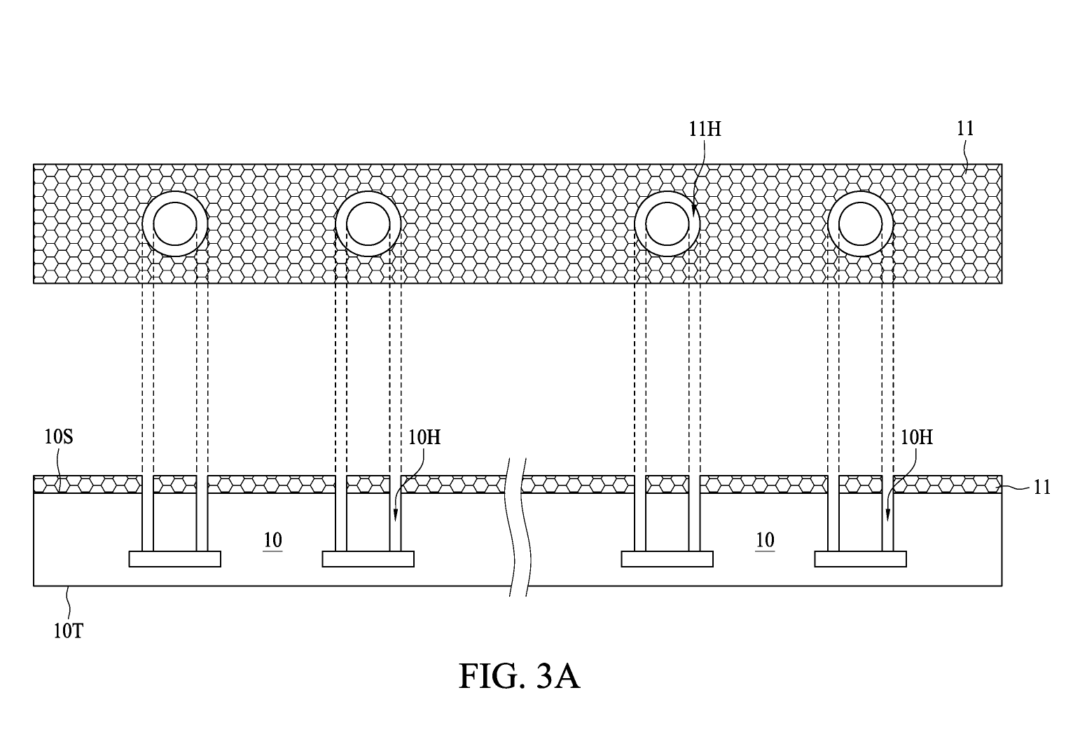

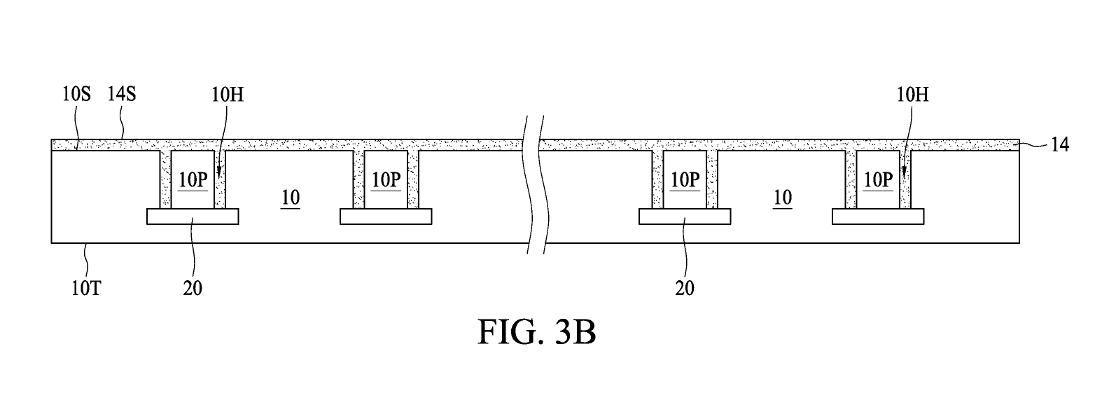

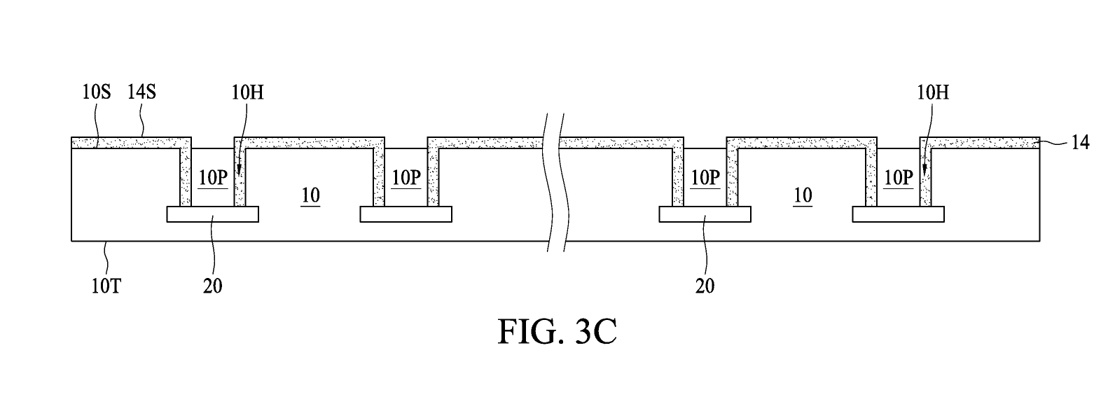

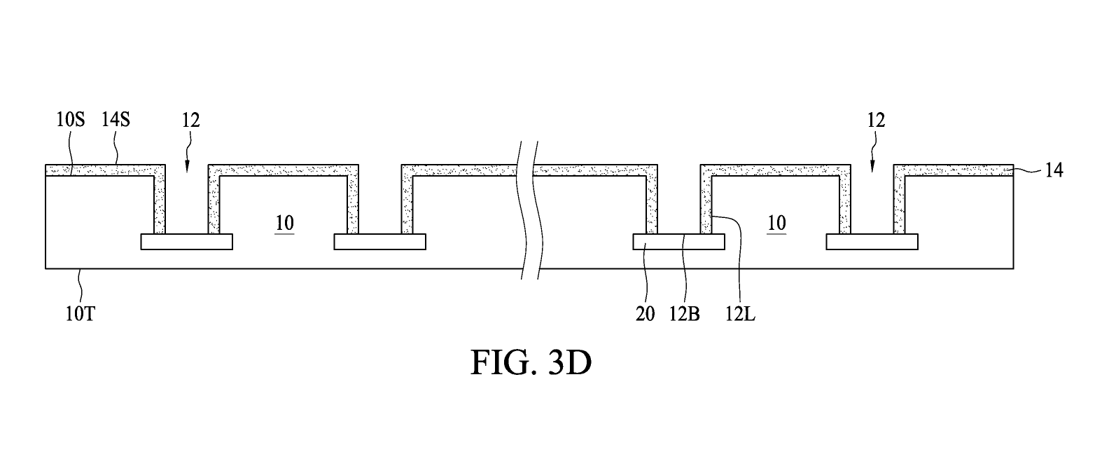

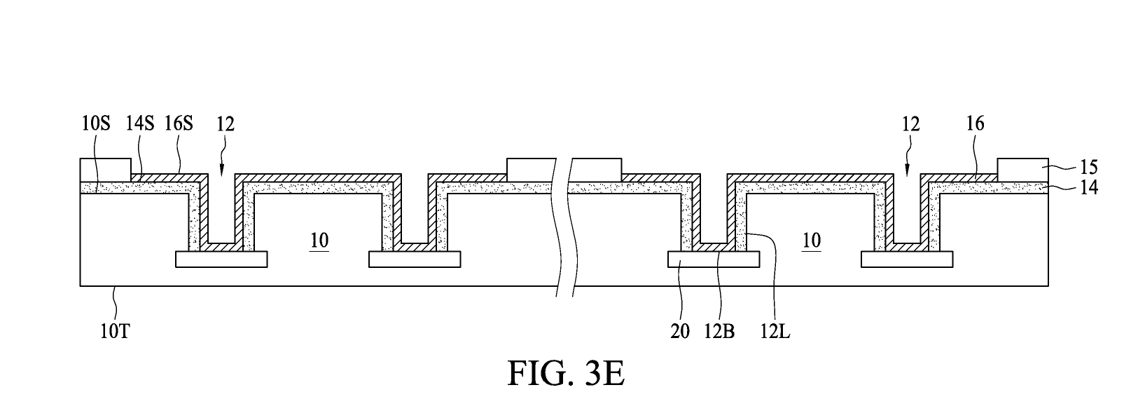

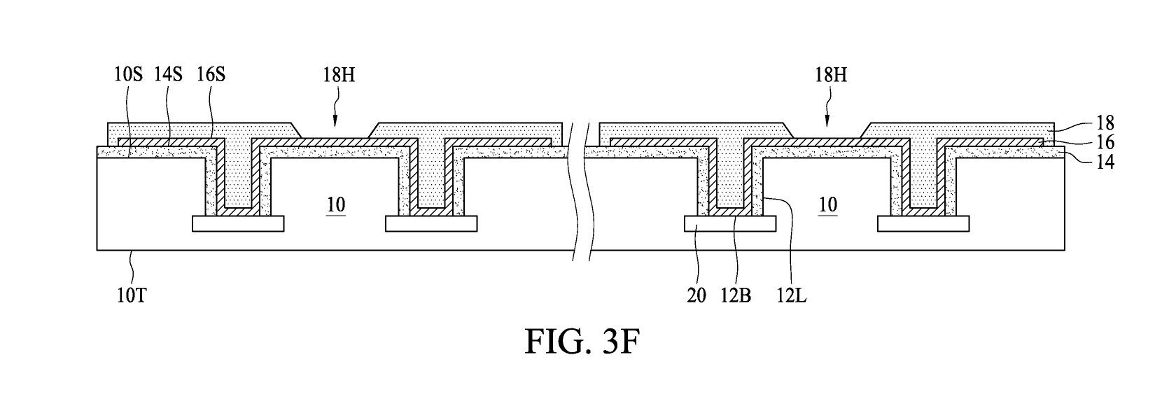

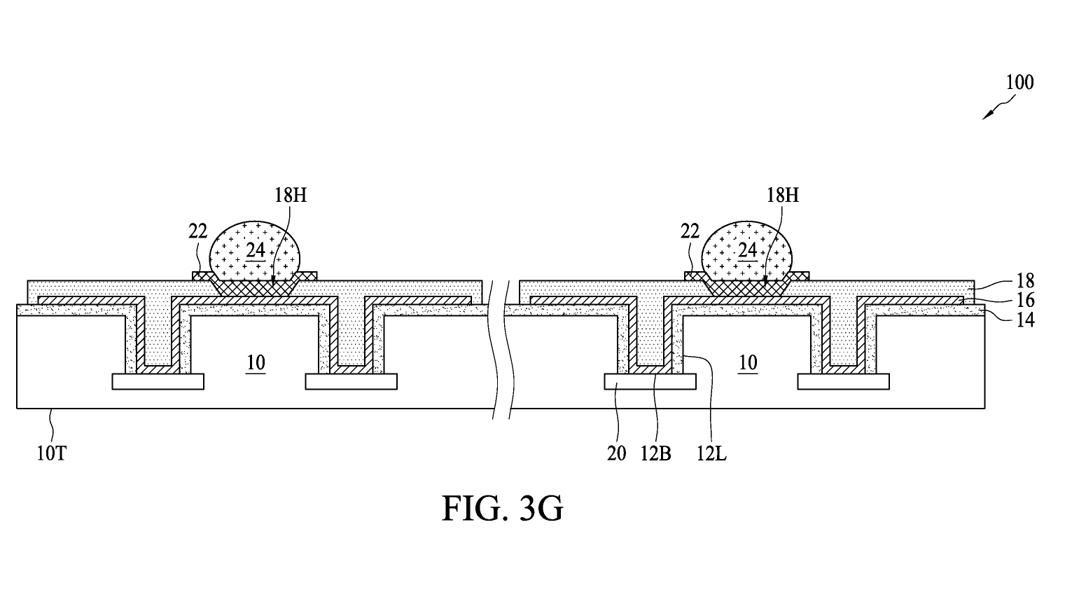

FIG. 3A through FIG. 3G illustrate a method of manufacturing a semiconductor wafer in accordance with some embodiments of the present disclosure. Referring to FIG. 3A, a substrate structure 10 is provided. In some embodiments, a wiring 20 is formed in the substrate structure 10. Then, a resist layer 11, such as a photoresist layer, is formed over the substrate structure 10. In some embodiments, the resist layer 11 has ring-shaped openings 11H exposing a portion of the substrate structure 10. The resist layer 11 is used as a mask to etch the substrate structure 10 to form several ring-shaped holes 10H. In some embodiments, each ring-shaped hole 10H exposes a portion of the wiring 20.

Referring to FIG. 3B, the resist layer 11 is removed. A first insulation layer 14 is formed over a first surface 10S of the substrate structure 10 and extending into the ring-shaped holes 10H of the substrate structure 10. The first insulation layer 14 extending into each ring-shaped hole 10H surrounds a portion 10P of the substrate structure 10. In some embodiments, a modulus of elasticity of the first insulation layer 14 is less than (e.g., substantially less than) about 1.7 GPa at room temperature. For example, the modulus of elasticity of the first insulation layer 14 is less than or equal to about 1.4 GPa at room temperature. In some embodiments, a CTE of the first insulation layer 14 is less than (e.g., substantially less than) about 46 ppm/° C. within a temperature range lower than its transition temperature. For example, the CTE of the first insulation layer 14 is less than or equal to about 39 ppm/° C. within a temperature range lower than its transition temperature.

Referring to FIG. 3C, the first insulation layer 14 is patterned to expose the portions 10P of the substrate structure 10 surrounded by the ring-shaped holes 10H. In some embodiments, the first insulation layer 14 is made of a photosensitive material, which can be patterned by photolithography techniques, and thus process steps are simplified and reduced.

Referring to FIG. 3D, the portions 10P of the substrate structure 10 are removed by, for example, etching, to form several vias 12 in the substrate structure 10. Since the first insulation layer 14 extends into the ring-shaped holes 10H, the first insulation layer 14 covers a lateral wall 12L of each via 12 subsequent to the portions 10P being removed. In some embodiments, the via 12 exposes the wiring 20 at a bottom surface 12B. Referring to FIG. 3E, another resist layer 15, such as a photoresist layer, is formed over the first insulation layer 14. The resist layer 15 exposes a portion of the first insulation layer 14 and the vias 12. Subsequently, a conductive layer 16 is formed over a surface 14S of the first insulation layer 14 and covering the bottom surfaces 12B exposed by the vias 12.

Referring to FIG. 3F, the resist layer 15 is removed. Subsequently, a second insulation layer 18 is formed over a surface 16S of the conductive layer 16. The second insulation layer 18 has or defines openings 18H exposing a portion of the conductive layer 16. In some embodiments, the second insulation layer 18 is made of a photosensitive material which can be patterned by photolithography techniques, and thus process steps are simplified and reduced. In some embodiments, a modulus of elasticity of the second insulation layer 18 is less than (e.g., substantially less than) about 1.7 GPa at room temperature. For example, the modulus of elasticity of the second insulation layer 18 is less than or equal to about 1.4 GPa at room temperature. In some embodiments, a CTE of the second insulation layer 18 is less than (e.g., substantially less than) about 46 ppm/° C. within a temperature range lower than its transition temperature. For example, the CTE of the second insulation layer 18 is less than or equal to about 39 ppm/° C. within a temperature range lower than its transition temperature.

Referring to FIG. 3G, conductive pads 22 and conductive bumps 24 are formed over the conductive layer 16 to form a semiconductor wafer 100. The conductive pads 22 are electrically connected to the conductive layer 16 through the openings 18H of the second insulation layer 18. The conductive bumps 24 are disposed on and electrically connected to their respective conductive pads 22. In some embodiments, the conductive pads 22 are configured as UBMs, and the conductive bumps 24 are configured as external terminals such as solder balls. The semiconductor wafer 100 can be then singulated to form several semiconductor packages 1 as illustrated in FIG. 2.

Table 1 lists a simulation result of insulation material property analysis of the semiconductor wafer 100 including the first insulation layer 14 and the second insulation layer 16 based on an FEM (finite element model). In this property analysis, the first insulation layer 14 and the second insulation layer 18 are made of the same insulation material. In Table 1, the term PA1 THK is the thickness of the first insulation layer 14; the term PA2 THK is the thickness of the second insulation layer 18; the term RDL THK is the thickness of the conductive layer 16; the term CT is the curing temperature of the first insulation layer 14 and the second insulation layer 18; the term Modulus is the modulus of elasticity of the first insulation layer 14 and the second insulation layer 18; the term CTE is the coefficient of thermal expansion of the first insulation layer 14 and the second insulation layer 18, the term Tg is the transition temperature of the first insulation layer 14 and the second insulation layer 18; and the term Warpage is the warpage of the semiconductor wafer 100.

TABLE 1

| | PA1 | PA2 | RDL | | | | | |
|---|---|---|---|---|---|---|---|---|
| | THK | THK | THK | | | | | Warpage |
| Cell | (μm) | (μm) | (μm) | CT (° C.) | Modulus | CTE | Tg | (μm) |
| 1 | 14 | 14 | 4.5 | 200 | 2.1 GPa | 65 ppm/° C. | 230° C. | 858.2 |
| 2 | 14 | 14 | 4.5 | 200 | 1.68 GPa | 65 ppm/° C. | 230° C. | 754.0 |
| 3 | 14 | 14 | 4.5 | 200 | 2.52 GPa | 65 ppm/° C. | 230° C. | 961.2 |
| 4 | 14 | 14 | 4.5 | 200 | 2.1 GPa | 52 ppm/° C. | 230° C. | 758.7 |
| 5 | 14 | 14 | 4.5 | 200 | 2.1 GPa | 78 ppm/° C. | 230° C. | 957.8 |
| 6 | 14 | 14 | 4.5 | 180 | 2.1 GPa | 65 ppm/° C. | 230° C. | 762.7 |
| 7 | 14 | 14 | 4.5 | 220 | 2.1 GPa | 65 ppm/° C. | 230° C. | 992.0 |
| 8 | 14 | 14 | 4.5 | 200 | 1.5 GPa | 65 ppm/° C. | 230° C. | 709.0 |
| 9 | 14 | 14 | 4.5 | 200 | 2.1 GPa | 45 ppm/° C. | 230° C. | 703.8 |
| 10 | 14 | 14 | 4.5 | 200 | 1.5 GPa | 45 ppm/° C. | 230° C. | 598.8 |
| 11 | 14 | 14 | 4.5 | 200 | 1.4 GPa | 39 ppm/° C. | 230° C. | 548.5 |

Referring to Table 1, as the moduli of elasticity and CTE of the first insulation layer 14 and the second insulation layer 18 are lowered, the warpage D of the semiconductor wafer 100 is alleviated. To meet the specification requirement of some semiconductor packages such as 3D semiconductor packages, the warpage D should be lower than about 550 micrometers. Thus, it is demonstrated that when the moduli of elasticity of the first insulation layer 14 and the second insulation layer 18 are lower than about 1.7 GPa and the CTEs are lower than about 46 ppm/° C., the warpage D of the semiconductor wafer 100 is alleviated to meet the warpage specification requirement.

The semiconductor package of the present disclosure is not limited to the above-mentioned embodiments, and may be implemented according to other embodiments. To simplify the description and for the convenience of comparison between various embodiments of the present disclosure, identical or similar components in each of the following embodiments are marked with identical numerals. For ease of highlighting the difference between the embodiments, the following description will detail the dissimilarities among different embodiments and the identical or similar features will not be redundantly described.

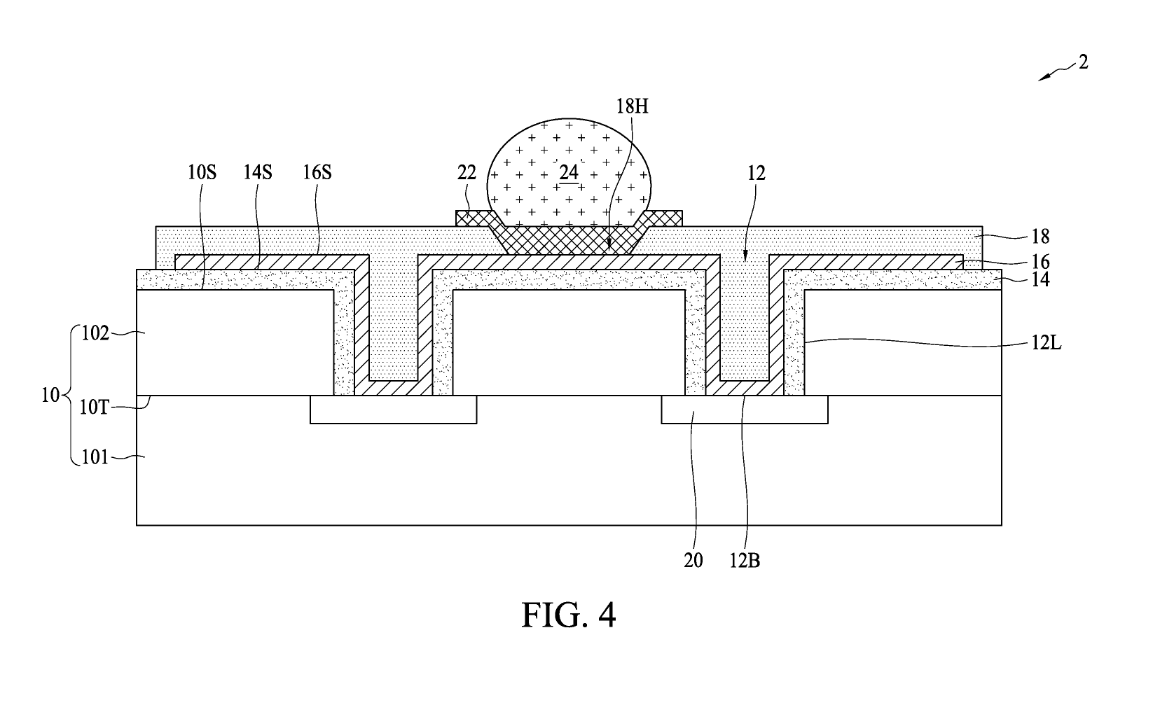

FIG. 4 is a cross-sectional view of a semiconductor package 2 in accordance with some embodiments of the present disclosure. Referring to FIG. 4, different from the semiconductor package 1 disclosed in FIG. 2 and related description, the semiconductor package 2 includes a substrate structure 10 including a semiconductor substrate 101 and an interposer 102. The semiconductor substrate 101 may be a bulk semiconductor substrate. The bulk semiconductor substrate may include an elemental semiconductor such as silicon or germanium; a compound semiconductor such as silicon germanium, silicon carbide, gallium arsenic, gallium phosphide, indium phosphide, or indium arsenide; or combinations thereof. In some embodiments, the semiconductor substrate 101 is a multi-layered substrate such as a SOI substrate, which includes a bottom semiconductor layer, a BOX and a top semiconductor layer. The interposer 102 is disposed over the semiconductor substrate 101. The interposer 102 may be a semiconductor interposer such as a silicon interposer. A wiring 20 is disposed between the semiconductor substrate 101 and the interposer 102, and a via 12 is a through via penetrating through the interposer 102 and exposing the wiring 20.

A first insulation layer 14 covers a first surface 10S of the substrate structure 10. Specifically, the first insulation layer 14 covers the first surface 10S of the interposer 102. The first insulation layer 14 extends into the via 12, covers a lateral wall 12L of the via 12 and exposes a bottom surface 12B through an opening at a bottom of the via 12. In some embodiments, the first insulation layer 14 is made of a photosensitive material which can be patterned by photolithography techniques, and thus process steps are simplified and reduced. A conductive layer 16 covers the first insulation layer 14 and the bottom surface 12B exposed by the first insulation layer 14. The conductive layer 16 is electrically connected to the wiring 20 through the through via 12. A second insulation layer 18 covers the conductive layer 16. In some embodiments, the second insulation layer 18 is made of a photosensitive material which can be patterned by photolithography techniques, and thus process steps are simplified and reduced.

A modulus of elasticity of the first insulation layer 14 is less than (e.g., substantially less than) about 1.7 GPa at room temperature. In some embodiments, the modulus of elasticity of the first insulation layer 14 is less than or equal to about 1.4 GPa at room temperature. A CTE of the first insulation layer 14 is less than (e.g., substantially less than) about 46 ppm/° C. within a temperature range lower than its transition temperature. In some embodiments, the CTE of the first insulation layer 14 is less than or equal to about 39 ppm/° C. within a temperature range lower than its transition temperature. A modulus of elasticity of the second insulation layer 18 is less than (e.g., substantially less than) about 1.7 GPa at room temperature. In some embodiments, the modulus of elasticity of the second insulation layer 18 is less than or equal to about 1.4 GPa at room temperature. A CTE of the second insulation layer 18 is less than (e.g., substantially less than) about 46 ppm/° C. within a temperature range lower than its transition temperature. In some embodiments, the CTE of the second insulation layer 18 is less than or equal to about 39 ppm/° C. within a temperature range lower than its transition temperature.

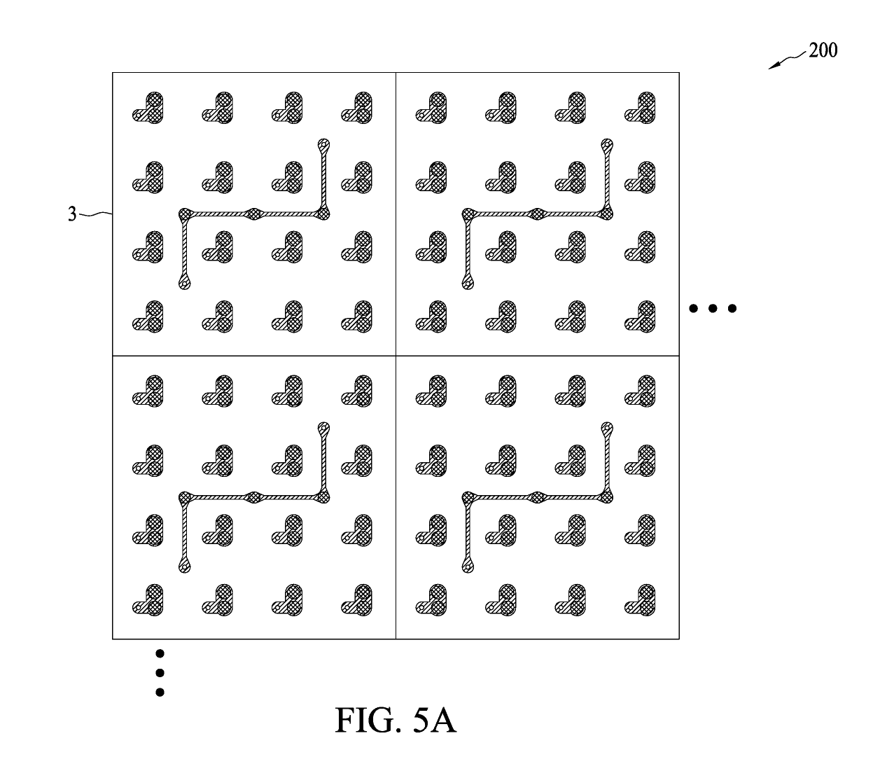

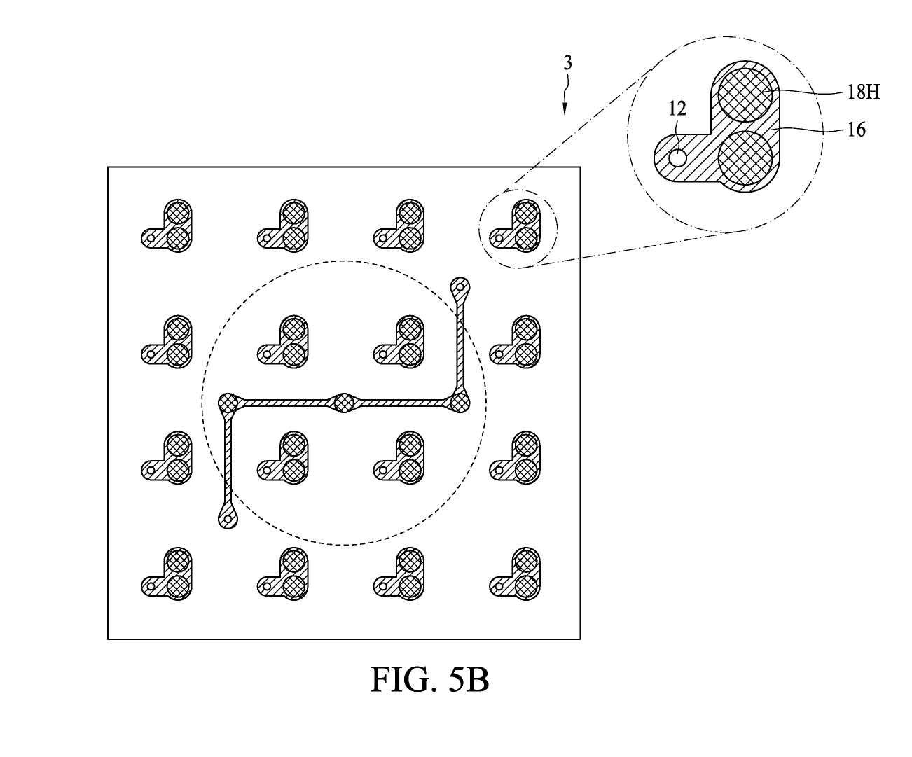

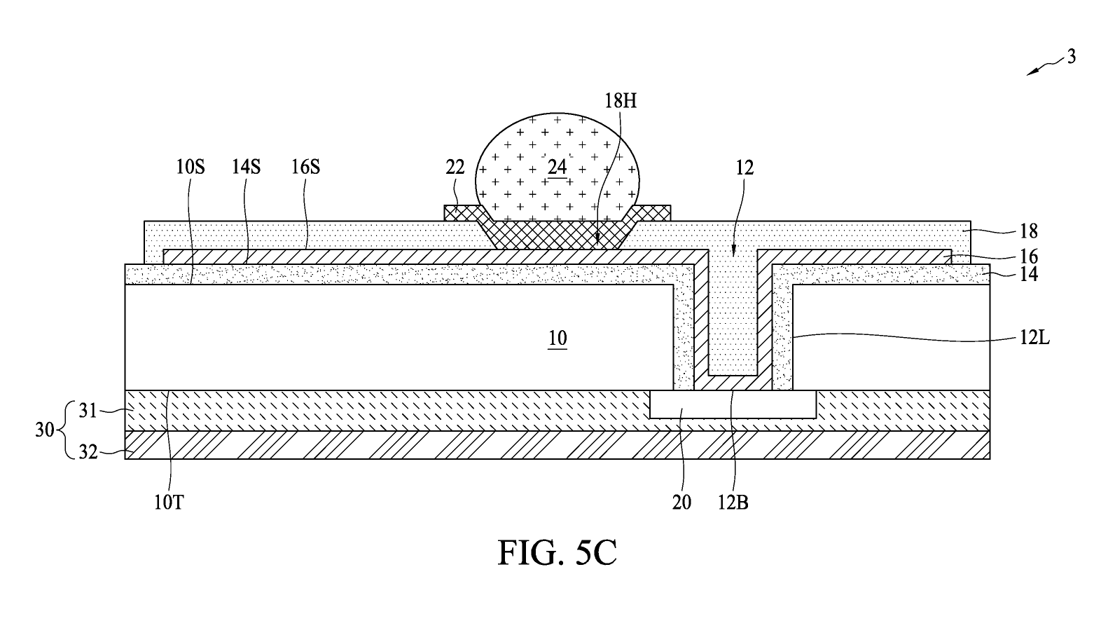

FIG. 5A is a top view of a semiconductor wafer 200 in accordance with some embodiments of the present disclosure, FIG. 5B is a top view of a semiconductor package 3 in accordance with some embodiments of the present disclosure, and FIG. 5C is a cross-sectional view of the semiconductor package 3 in accordance with some embodiments of the present disclosure. Referring to FIG. 5A, the semiconductor wafer 200 includes an array of semiconductor packages 3. Referring to FIG. 5B and FIG. 5C, the semiconductor package 3 includes a substrate structure 10, a first insulation layer 14, a conductive layer 16 and a second insulation layer 18. The substrate structure 10 has or defines at least one via 12 which exposes a wiring 20. In some embodiments, the wiring 20 is an electrical terminal of a device formed in the substrate structure 10. The first insulation layer 14 covers a first surface 10S of the substrate structure 10. The first insulation layer 14 extends into the via 12, covers a lateral wall 12L of the via 12 and exposes a bottom surface 12B through an opening at a bottom of the via 12. In some embodiments, the bottom surface 12B is an exposed surface of the wiring 20, and thus the first insulation layer 14 exposes the wiring 20 through the via 12. In some embodiments, a thickness of the first insulation layer 14 ranges from about 5 micrometers to about 20 micrometers, such as, for example, about 14 micrometers, but is not limited thereto. The conductive layer 16 covers a surface 14S of the first insulation layer 14 and the bottom surface 12B exposed by the first insulation layer 14. In some embodiments, the conductive layer 16 is in contact with the wiring 20 exposed by the first insulation layer 14 through the via 12, thereby electrically connecting to the wiring 20. In some embodiments, the thickness of the conductive layer 16 ranges from about 3 micrometers to about 15 micrometers, such as, for example, about 4.5 micrometers or about 6.5 micrometers, but is not limited thereto. The second insulation layer 18 covers a surface 16S of the conductive layer 16. In some embodiments, the second insulation layer 18 has or defines an opening 18H exposing a portion of the conductive layer 16. In some embodiments, a thickness of the second insulation layer 18 ranges from about 5 micrometers to about 20 micrometers, such as, for example, about 14 micrometers, but is not limited thereto.

In some embodiments, the semiconductor package 3 further includes a conductive pad 22 and a conductive bump 24. The conductive pad 22 is electrically connected to the conductive layer 16 through the opening 18H of the second insulation layer 18. The conductive bump 24 is disposed on and electrically connected to the conductive pad 22. In some embodiments, the conductive pad 22 is configured as an UBM, and the conductive bump 24 is configured as an external terminal such as a solder ball. The conductive bump 24 can be electrically connected to another conductive structure such as a chip, thereby forming a 3D package structure.

The semiconductor package 3 further includes a balance layer 30 disposed over a second surface 10T (e.g., a bottom surface) of the substrate structure 10. The balance layer 30 is more robust than the substrate structure 10 and overlying layers on the substrate structure 10, and thus is able to reduce a warpage of the substrate structure 10. In some embodiments, the robustness refers to either, or both, hardness or modulus of elasticity. The hardness and the modulus of elasticity of the balance layer 30 is higher than those of the substrate structure 10 and the overlying layers on the substrate structure 10. In some embodiments, the hardness of the balance layer 30 ranges from about 600 kg/mm² to about 2000 kg/mm², such as, for example, about 1500 kg/mm². In some embodiments, the modulus of elasticity of the balance layer 30 ranges from about 200 GPa to about 400 GPa, such as, for example, about 310 GPa. As illustrated in FIG. 5C, the balance layer 30 is a multi-layered balance layer, which includes, but is not limited to, a silicon oxide layer 31 over the second surface 10T, and a silicon nitride layer 32 over the silicon oxide layer 31. In some embodiments, a thickness of the silicon oxide layer 31 ranges from about 0.5 micrometers to about 6 micrometers, such as, for example, about 2.7 micrometers; and a thickness of the silicon nitride layer 32 ranges from about 0.5 micrometers to about 2 micrometers. During manufacturing of the semiconductor package 3, the balance layer 30 is formed over the second surface 10T of the substrate structure 10 by a suitable deposition technique.

Table 2 lists a simulation result of warpage of the semiconductor wafer 200 including the balance layer 30 formed of the silicon oxide layer 31 and the silicon nitride layer 32 covering the second surface 10T of the substrate structure 10. In the simulation, the warpage is measured on a 4*4 array of the semiconductor packages 3 at 25° C. Referring to Table 2, with the balance layer 30 disposed over the second surface 10T of the substrate structure 10, the warpage D is reduced to less than about 550 micrometers.

TABLE 2

| | Max warpage | Max |
|---|---|---|
| | (μm) at | stress in Z axis (MPa) |
| 4 * 4 array of package structure | 25° C. | at 25° C. |
| Silicon nitride layer (0.5 μm) | 478.47 | 458.78 |
| Silicon nitride layer (1.0 μm) | 460.72 | 462.52 |
| Silicon nitride layer (1.5 μm) | 445.06 | 465.76 |
| Silicon nitride layer (2.0 μm) | 431.12 | 468.61 |

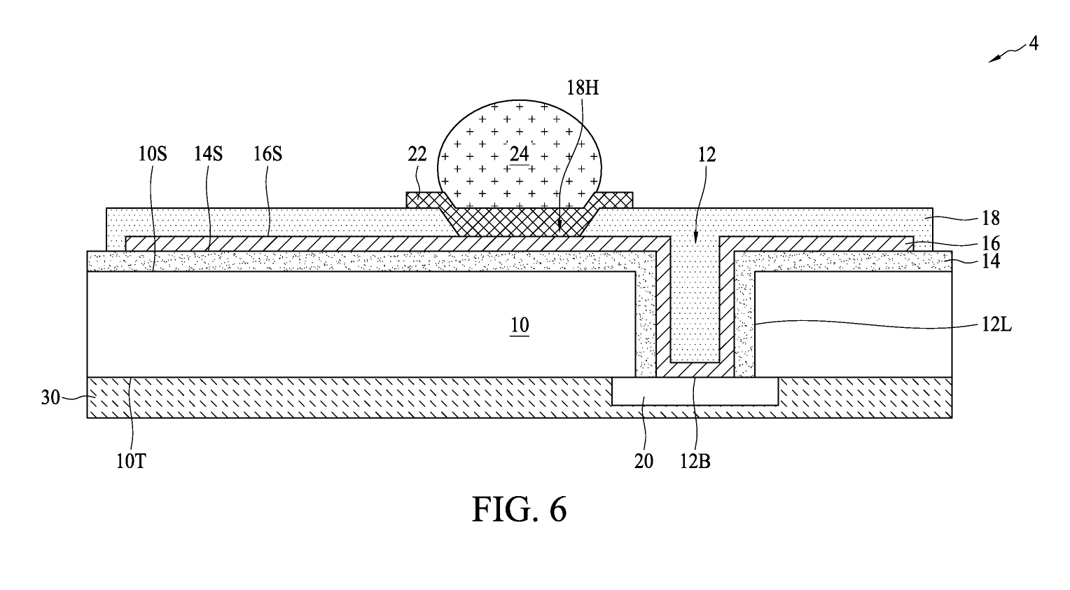

FIG. 6 is a cross-sectional view of a semiconductor package 4 in accordance with some embodiments of the present disclosure. Referring to FIG. 6, different from the semiconductor package 3 of FIG. 5C, a balance layer 30 of the semiconductor package 4 is a single-layered balance layer. In some embodiments, the balance layer 30 may be a silicon nitride layer, silicon oxide layer, silicon carbide layer, or other suitable balance layer more robust than a substrate structure 10 and overlying layers on the substrate structure 10.

In conclusion, a semiconductor wafer of some embodiments of the present disclosure is configured to have a warpage less than (e.g., substantially less than) about 550 micrometers, and thus the reliability of semiconductor packages singulated from the semiconductor wafer is improved.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation about 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor wafer, comprising:
a substrate structure defining a via;
a first insulation layer covering a first surface of the substrate structure, wherein the first insulation layer extends into the via, covers a lateral wall of the via and exposes a bottom surface at a bottom of the via;
a conductive layer covering the first insulation layer and the bottom surface exposed by the first insulation layer;
a second insulation layer covering the conductive layer, wherein the second insulation layer defines an opening exposing a portion of the conductive layer; and
a conductive pad disposed over the second insulation layer, wherein the conductive pad is electrically connected to the conductive layer through the opening of the second insulation layer;
wherein a warpage of the semiconductor wafer is less than 550 micrometers.

2. The semiconductor wafer of claim 1, wherein a modulus of elasticity of the first insulation layer and a modulus of elasticity of the second insulation layer are each less than 1.7 GPa.

3. The semiconductor wafer of claim 2, wherein the modulus of elasticity of the first insulation layer and the modulus of elasticity of the second insulation layer are each less than or equal to 1.4 GPa.

4. The semiconductor wafer of claim 1, wherein a coefficient of thermal expansion of the first insulation layer and a coefficient of thermal expansion of the second insulation layer are each less than 46 ppm/° C.

5. The semiconductor wafer of claim 4, wherein the coefficient of thermal expansion of the first insulation layer and the coefficient of thermal expansion of the second insulation layer are each less than or equal to 39 ppm/° C.

6. The semiconductor wafer of claim 1, wherein the first insulation layer and the second insulation layer comprise a the same photosensitive material.

7. (canceled)

8. The semiconductor wafer of claim 1, further comprising:
a conductive bump disposed on the conductive pad.

9. The semiconductor wafer of claim 1, wherein the substrate structure is a semiconductor substrate, the semiconductor wafer further comprises a wiring embedded in the semiconductor substrate, the wiring is exposed by the via, and the conductive layer is electrically connected to the wiring through the via.

10. The semiconductor wafer of claim 1, wherein the substrate structure comprises a semiconductor substrate and an interposer over the semiconductor substrate, the semiconductor wafer further comprises a wiring between the semiconductor substrate and the interposer, the via is a through via penetrating through the interposer and exposing the wiring, and the conductive layer is electrically connected to the wiring through the via.

11. The semiconductor wafer of claim 1, further comprising a balance layer over a second surface of the substrate structure opposite to the first surface of the substrate structure, wherein a modulus of elasticity of the balance layer is more than or equal to 200 GPa.

12. A semiconductor package, comprising:
a substrate structure defining a via;
a first insulation layer covering a first surface of the substrate structure, wherein the first insulation layer extends into the via, covers a lateral wall of the via and exposes a bottom surface at a bottom of the via;
a conductive layer covering the first insulation layer and the bottom surface exposed by the first insulation layer; and
a second insulation layer covering the conductive layer, wherein the second insulation layer fills up the via;
wherein a modulus of elasticity of the first insulation layer and a modulus of elasticity of the second insulation layer are each less than 1.7 GPa.

13. The semiconductor package of claim 12, wherein the modulus of elasticity of the first insulation layer and the modulus of elasticity of the second insulation layer are each less than or equal to 1.4 GPa.

14. The semiconductor package of claim 12, wherein a coefficient of thermal expansion of the first insulation layer and a coefficient of thermal expansion of the second insulation layer are each less than 46 ppm/° C.

15. The semiconductor package of claim 14, wherein the coefficient of thermal expansion of the first insulation layer and the coefficient of thermal expansion of the second insulation layer are each less than or equal to 39 ppm/° C.

16. The semiconductor package of claim 12, further comprising a balance layer over a second surface of the substrate structure opposite to the first surface of the substrate structure.

17. A method for manufacturing a semiconductor wafer, comprising:
providing a substrate structure defining a via;
forming a first insulation layer over a first surface of the substrate structure and extending into the via to cover a lateral wall of the via and expose a bottom surface at a bottom of the via, wherein the first insulation layer comprises a photosensitive material;
forming a conductive layer over the first insulation layer and the bottom surface exposed by the first insulation layer;
forming a second insulation layer over the conductive layer, wherein the second insulation layer defines an opening exposing a portion of the conductive layer; and
forming a conductive pad over the second insulation layer, wherein the conductive pad is electrically connected to the conductive layer through the opening of the second insulation layer

18. The method of claim 17, wherein a modulus of elasticity of the first insulation layer and a modulus of elasticity of the second insulation layer are each less than 1.7 GPa.

19. The method of claim 17, wherein a coefficient of thermal expansion of the first insulation layer and a coefficient of thermal expansion of the second insulation layer are each less than 46 ppm/° C.

20. The method of claim 17, further comprising forming a balance layer over a second surface of the substrate structure opposite to the first surface of the substrate structure.
